(19) United States
(12) Patent Application Publication
(10) Pub. No.: US 2010/0296259 A1
(43) Pub. Date: Nov. 25, 2010

(54) ELECTRONIC DEVICE

(75) Inventor: PIN-SHU KUNG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/608,167

(22) Filed: Oct. 29, 2009

(30) Foreign Application Priority Data
May 22, 2009 (CN) 200920303443.2

(51) Int. Cl. H05K 7/00

(52) U.S. Cl. 361/807

(57) ABSTRACT

An electronic device includes an enclosure accommodating a plurality of electronic elements therein and a clasping member to determine if the enclosure has been disconnected. The enclosure includes a cover, a base, and a retaining member including a pair of receiving portions. One of the pair of receiving portions projects from an inner surface of the cover, while the other receiving portion projects from an inner surface of the base corresponding to the one receiving portion. The clasping member is received in the pair of receiving portions when the cover is mounted on the base. The clasping member is capable of being broken in response to the cover being disengaged from the base.

### BACKGROUND

1. Technical Field

The present disclosure relates to electronic devices, and more particularly to an electronic device with a clasping member to determine if an enclosure of the electronic device has been disassembled.

2. Description of Related Art

A seal to indicate when a user has disassembled an electronic device is frequently attached to an exterior of an enclosure of the electronic device with an adhesive. However, it is difficult to detach the seal from the enclosure later on when needed. In addition, the adhesive may leave a stain marring the aesthetic appearance of the electronic device.

Therefore, a need exists in the industry to overcome the described limitations.

### BRIEF DESCRIPTION OF THE DRAWINGS

FIG. 1 is an exploded, isometric view of an electronic device of an exemplary embodiment of the disclosure.

FIG. 2 is an assembled view of FIG. 1.

FIG. 3 is a cross-sectional view taken along line III-III of FIG. 2.

### DETAILED DESCRIPTION

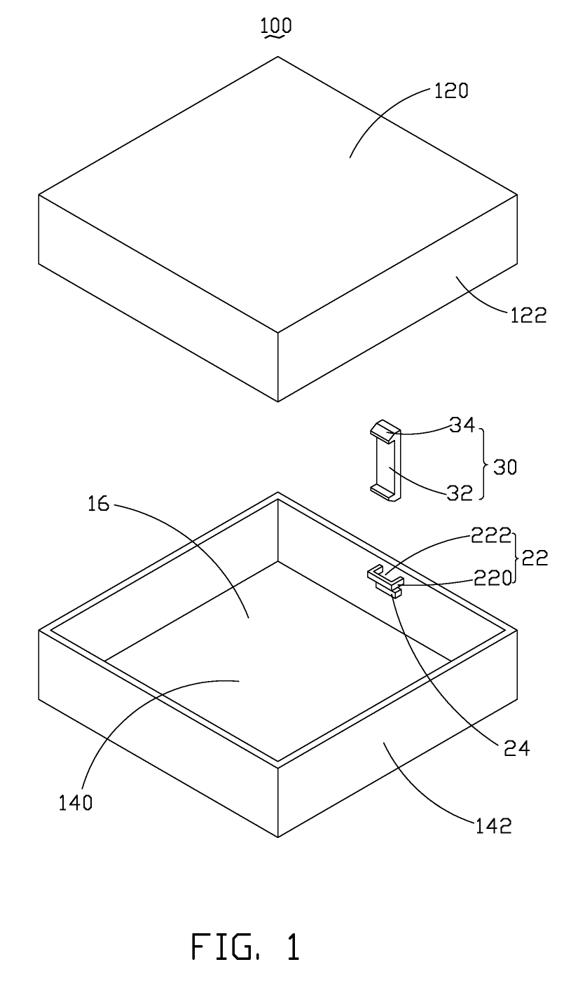

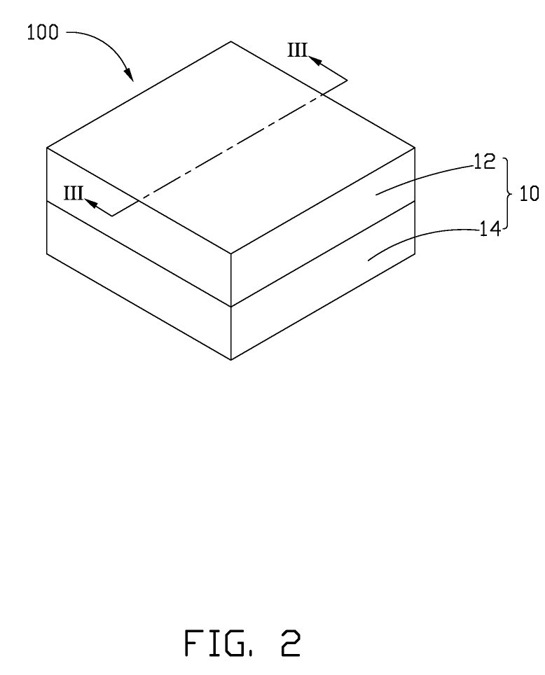

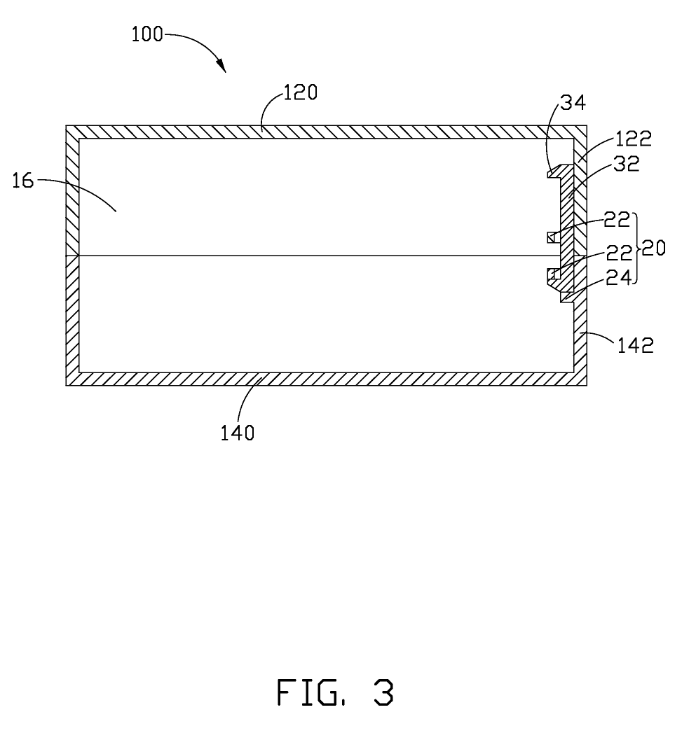

Referring to FIG. 1 to FIG. 3, an electronic device 100 of an exemplary embodiment of the present disclosure is illustrated. The electronic device 100 includes an enclosure 10 and a clasping member 30 to determine if the enclosure 10 has been disassembled. The electronic device 100 may be a computer, such as a laptop, or a mobile internet device (MID), but the disclosure is not limited thereto.

The enclosure 10 accommodates electronic elements, such as, printed circuit boards (PCBs), batteries, and/or a central processing unit (CPU), for example. The enclosure 10 is substantially rectangular and it will be understood that other configurations may be utilized. The enclosure 10 includes a top wall 120, a bottom wall 140, a plurality of first sidewalls 122, and a plurality of second sidewalls 142.

In the illustrated embodiment, the top wall 120 and the first sidewalls 122 cooperatively define a cover 12 of the enclosure 10, while the bottom wall 140 and the second sidewalls 142 cooperatively define a base 14 of the enclosure 10.

In the illustrated embodiment, the cover 12 is mechanically connected to the base 14, where a receiving space 16 is formed in an interior of the enclosure 10 for receiving the electronic elements. Alternatively, the receiving space 16 may be formed in an interior of the cover 12 or the base 14.

The enclosure 10 further includes a retaining member 20 including a pair of receiving portions 22 and a block portion 24. The pair of receiving portions 22 project from inner surfaces of a pair of corresponding sidewalls. That is, one of the pair of receiving portions 22 projects from an inner surface of one of the plurality of first sidewalls 122, while the other receiving portion 22 projects from an inner surface of one of the plurality of second sidewalls 142 corresponding to the first sidewall 122. Each of the pair of receiving portions 22 is substantially n-shaped, and includes a frame 220 and a receiving hole 222 formed between the frame 220 and a corresponding sidewall to receiving the clasping member 30.

The block portion 24 is adjacent to a side of one of the pair of receiving portions 22 apart from the other receiving portion 22 to limit movement of the clasping member 30. In the illustrated embodiment, the block portion 24 projects from the inner surface of the second sidewall 142.

The clasping member 30 includes a main body 32 and a pair of hooks 34 located at distal ends of the main body 32. A thickness of the main body 32 is less than a depth of each of the pair of receiving holes 222 so that the clasping member 30 can easily extend through the pair of receiving holes 222. A height of each of the pair of hooks 34 is greater than the depth of each of the pair of receiving holes 222 so that the pair of hooks 34 can clasp the pair of frames 220, avoiding disengagement of the clasping member 30 from the receiving portion 22.

In assembly, one of the pair of hooks 34 of the clasping member 30 extends through the receiving hole 222 of one of the pair of receiving portions 22 to clasp the frame 220 of the one of the pair of receiving portions 22, and abuts against the block portion 24, while the other hook 34 extends through the other receiving hole 222, so that the cover 12 is mounted on the base 14. Thus, the clasping member 30 is assembled in the interior of the enclosure 10.

In use, if the cover 12 is disengaged from the base 14, the clasping member 30 is capable of being broken, to clearly indicating to service personnel of the manufacturer that the electronic device 100 was disassembled, possibly voiding any warranties.

Because the clasping member 30 is assembled in the interior of the enclosure 10, aesthetic appearance of the electronic device 100 is preserved.

While an embodiment of the present disclosure has been described above, it should be understood that it has been presented by way of example only and not by way of limitation. Thus the breadth and scope of the present disclosure should not be limited by the above-described embodiments, but should be defined only in accordance with the following claims and their equivalents.

What is claimed is:

1. An electronic device comprising:
an enclosure accommodating a plurality of electronic elements therein, the enclosure comprising a cover, a base, and a retaining member comprising a pair of receiving portions, wherein one of the pair of receiving portions projects from an inner surface of the cover, while the other receiving portion projects from an inner surface of the base corresponding to the one receiving portion; and
a clasping member to determine if the enclosure has been disassembled, wherein the clasping member is received in the pair of receiving portions when the cover is mounted on the base;
wherein the clasping member is capable of being broken in response to the cover being disengaged from the base.

2. The electronic device as recited in claim 1, wherein the retaining member further comprises a block portion projecting from the inner surface of one of the cover and the base and adjacent to a side of one of the pair of receiving portions.

3. The electronic device as recited in claim 1, wherein each of the pair of receiving portions is substantially n-shaped.

4. The electronic device as recited in claim 3, wherein each of the pair of receiving portions comprises a frame and a receiving hole formed between the frame and the inner surface of one of the cover and the base.

5. The electronic device as recited in claim 4, wherein the clasping member comprises a main body and a pair of hooks located distal ends of the main body.

6. The electronic device as recited in claim 5, wherein a thickness of the main body is less than a depth of each of the pair of receiving holes.

7. The electronic device as recited in claim 5, wherein a height of each of the pair of hooks is greater than a depth of each of the pair of receiving holes.
